(19) United States
(12) Patent Application Publication
(10) Pub. No.: US 2025/0206597 A1
(43) Pub. Date: Jun. 26, 2025

(54) NANOGAP DIELECTRIC MATERIAL

(71) Applicant: Robert Bosch GmbH, Stuttgart (DE)

(72) Inventors: Mordechai KORNBLUTH, Brighton, MA (US); Armin DARVISH, Daly City, CA (US); Charles TUFFILE, Swansea, MA (US)

(21) Appl. No.: 18/390,637

(22) Filed: Dec. 20, 2023

(51) Int. Cl. B82Y 30/00; B81B 3/00; B82Y 15/00; H01B 3/10

(52) U.S. Cl. CPC B81B 3/0086; B82Y 15/00; B82Y 30/00; H01B 3/10; B81B 2203/0127

(57) ABSTRACT

A nanogap dielectric device including a substrate supporting a nano cathode and a nano anode separated from each other by a nanogap and a dielectric nano material located within the nanogap, the dielectric nano material comprising one or more compounds of formula (II):

M_{1-x-y}CrₓO_{y} (II),

where M is a metal, x is any number between 0.077 and 0.114 or 0.179 and 0.3, and y is any number between 0.618 and 0.75.

### TECHNICAL FIELD

The present disclosure relates to a nanogap dielectric material for electronic, optical and/or bio devices and the method of making the same.

### BACKGROUND

With advancing tools and methods, nanoscale manufacturing is gaining traction. Yet, the science and engineering of structures, devices, and systems made of atoms on the nanoscale requires new material approaches such that the desired nano structures may be formed and function in a desired way.

### SUMMARY

In one or more embodiments, a nanogap dielectric device is disclosed. The device may include a pair of nano electrodes, a nanogap separating the electrodes, and a dielectric nano material located within the nanogap, the dielectric nano material comprising one or more compounds of formula (I):

(Nd,Ca)O₂ (I)

The dielectric nano material may have a bandgap of at least about 2 eV. The dielectric nano material may have a dielectric constant of at least about 10. The dielectric nano material may form a layer having a thickness of about 3-100 nm and a width at least about 10 times greater than the thickness. The dielectric nano material may be in contact with only one nano electrode from the pair of nano electrodes. The dielectric nano material may also include one or more compounds of formula (II):

M_{1-x-y}CrₓO_{y} (II),
where
M is a metal,
x is any number between 0.077 and 0.114 or 0.179 and 0.3, and
y is any number between 0.618 and 0.75.

The material may include an oxygen vacancy such that the oxygen content is O_{2-δ}, where 0≤δ<0.5. The device may be a nanoelectromechanical systems (NEMS) device.

In another embodiment, a nanogap dielectric device is disclosed. The device may include a substrate supporting a nano cathode and a nano anode separated from each other by a nanogap, and a dielectric nano material located within the nanogap, the dielectric nano material comprising one or more compounds of formula (II):

M_{1-x-y}CrₓO_{y} (II),
where
M is a metal,
x is any number between 0.077 and 0.114 or 0.179 and 0.3, and
y is any number between 0.618 and 0.75.

The dielectric nano material may have a bandgap of at least about 2 eV. The dielectric nano material may have a dielectric constant of at least about 10. The dielectric nano material may form a layer having a thickness of about 3-100 nm and a width at least about 10 times greater than the thickness. The dielectric nano material may be in contact with the nano cathode or the nano anode. The dielectric nano material may further include one or more compounds of formula (III):

MₓV_{y}O_{1-x-y} (III),
where
M is a metal,
x is any number greater than 0.1, and
y is any number greater than 0.138.

The device may further include a graphene or chemical monolayer membrane bridging the nanogap.

In yet another embodiment, a nanogap dielectric device is disclosed. The device may include a substrate supporting a first conductor and a second conductor, separated from the first conductor by a nanogap and a dielectric nano material located within the nanogap, the dielectric nano material comprising one or more compounds of formula (III):

MₓV_{y}O_{1-x-y} (III),
where
M is a metal,
x is any number greater than 0.1,
y is any number greater than 0.138.

The dielectric nano material may have a bandgap of at least about 2 eV. The dielectric nano material may have a dielectric constant of at least about 10. The dielectric nano material may be non-stoichiometric. The dielectric nano material may be in contact with the first conductor and the substrate, but not with the second conductor.

### BRIEF DESCRIPTION OF THE DRAWINGS

FIG. 1 is a schematic depiction of a non-limiting example nano device with a dielectric;

FIG. 2 is a schematic depiction of a nanoscale device current collectors sandwiching a dielectric;

FIG. 3 is a schematic depiction of a non-limiting example nanoelectromechanical systems (NEMS) capacitive switch including a dielectric material disclosed herein;

FIG. 4 shows an example algorithm for bandgap screening of decomposition products disclosed herein;

FIG. 5 is a plot showing bandgap decomposition for screened materials;

FIG. 6 is a scatterplot summarizing results of the binary oxides screening of the Experimental section;

FIG. 7 is a scatterplot summarizing results of the ternary oxides screening of the Experimental section;

FIG. 8 is a plot showing bandgap decomposition for ternary oxides;

FIG. 9 is a decision tree for the ternary oxides of the Experimental section;

FIG. 10 is a scatterplot summarizing results of the nitrides screening of the Experimental section;

FIG. 11 is a plot showing bandgap decomposition for nitrides; and

FIG. 12 is a decision tree for the nitrides of the Experimental section.

### DETAILED DESCRIPTION

Embodiments of the present disclosure are described herein. It is to be understood, however, that the disclosed embodiments are merely examples and other embodiments may take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present embodiments. As those of ordinary skill in the art will understand, various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Except in the examples, or where otherwise expressly indicated, all numerical quantities in this description indicating amounts of material or conditions of reaction and/or use are to be understood as modified by the word “about” in describing the broadest scope of the disclosure. Practice within the numerical limits stated is generally preferred. Also, unless expressly stated to the contrary: percent, “parts of,” and ratio values are by weight; the description of a group or class of materials as suitable or preferred for a given purpose in connection with the disclosure implies that mixtures of any two or more of the members of the group or class are equally suitable or preferred; description of constituents in chemical terms refers to the constituents at the time of addition to any combination specified in the description, and does not necessarily preclude chemical interactions among the constituents of a mixture once mixed.

The first definition of an acronym or other abbreviation applies to all subsequent uses herein of the same abbreviation and applies mutatis mutandis to normal grammatical variations of the initially defined abbreviation. Unless expressly stated to the contrary, measurement of a property is determined by the same technique as previously or later referenced for the same property.

It must also be noted that, as used in the specification and the appended claims, the singular form “a,” “an,” and “the” comprise plural referents unless the context clearly indicates otherwise. For example, reference to a component in the singular is intended to comprise a plurality of components.

As used herein, the term “substantially,” “generally,” or “about” means that the amount or value in question may be the specific value designated or some other value in its neighborhood. Generally, the term “about” denoting a certain value is intended to denote a range within ±5% of the value. As one example, the phrase “about 100” denotes a range of 100±5, i.e. the range from 95 to 105. Generally, when the term “about” is used, it can be expected that similar results or effects according to the disclosure can be obtained within a range of ±5% of the indicated value. The term “substantially” may modify a value or relative characteristic disclosed or claimed in the present disclosure. In such instances, “substantially” may signify that the value or relative characteristic it modifies is within ±0%, 0.1%, 0.5%, 1%, 2%, 3%, 4%, 5% or 10% of the value or relative characteristic.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits.

In the examples set forth herein, concentrations, temperature, and reaction conditions (e.g., pressure, pH, flow rates, etc.) can be practiced with plus or minus 50 percent of the values indicated rounded to or truncated to two significant figures of the value provided in the examples. In a refinement, concentrations, temperature, and reaction conditions (e.g., pressure, pH, flow rates, etc.) can be practiced with plus or minus 30 percent of the values indicated rounded to or truncated to two significant figures of the value provided in the examples. In another refinement, concentrations, temperature, and reaction conditions (e.g., pressure, pH, flow rates, etc.) can be practiced with plus or minus 10 percent of the values indicated rounded to or truncated to two significant figures of the value provided in the examples.

For all compounds expressed as an empirical chemical formula with a plurality of letters and numeric subscripts (e.g., CH₂O), values of the subscripts can be plus or minus 50 percent of the values indicated rounded to or truncated to two significant figures. For example, if CH₂O is indicated, a compound of formula C_{(0.8-1.2)}H_{(1.6-2.4)}O_{(0.8-1.2)}. In a refinement, values of the subscripts can be plus or minus 30 percent of the values indicated rounded to or truncated to two significant figures. In still another refinement, values of the subscripts can be plus or minus 20 percent of the values indicated rounded to or truncated to two significant figures.

As used herein, the term “and/or” means that either all or only one of the elements of said group may be present. For example, “A and/or B” means “only A, or only B, or both A and B”. In the case of “only A,” the term also covers the possibility that B is absent, i.e. “only A, but not B”.

It is also to be understood that this disclosure is not limited to the specific embodiments and methods described below, as specific components and/or conditions may, of course, vary. Furthermore, the terminology used herein is used only for the purpose of describing particular embodiments of the present disclosure and is not intended to be limiting in any way.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

With respect to the terms “comprising,” “consisting of,” and “consisting essentially of,” where one of these three terms is used herein, the presently disclosed and claimed subject matter can include the use of either of the other two terms.

The term “one or more” means “at least one” and the term “at least one” means “one or more.” The terms “one or more” and “at least one” include “plurality” as a subset.

The description of a group or class of materials as suitable for a given purpose in connection with one or more embodiments implies that mixtures of any two or more of the members of the group or class are suitable. Description of constituents in chemical terms refers to the constituents at the time of addition to any combination specified in the description, and does not necessarily preclude chemical interactions among constituents of the mixture once mixed. First definition of an acronym or other abbreviation applies to all subsequent uses herein of the same abbreviation and applies mutatis mutandis to normal grammatical variations of the initially defined abbreviation. Unless expressly stated to the contrary, measurement of a property is determined by the same technique as previously or later referenced for the same property.

In the past, manufacturing was focused on dimensions visible with the naked eye. Nowadays, new tools, systems, and solutions are enabling manufacturing at much smaller scales such as nanoscale. Nanomanufacturing is a set of industrial processes based on nanotechnology, where products are developed at the nanoscale. Nanotechnology is the science and engineering of structures, devices, and systems made of atoms arranged on the 1 to 100 nm length scale. While in the past, manufacturing was influenced by nanoscale-such as defects or advantageous structures on the nanoscale of materials-their presence was not controlled.

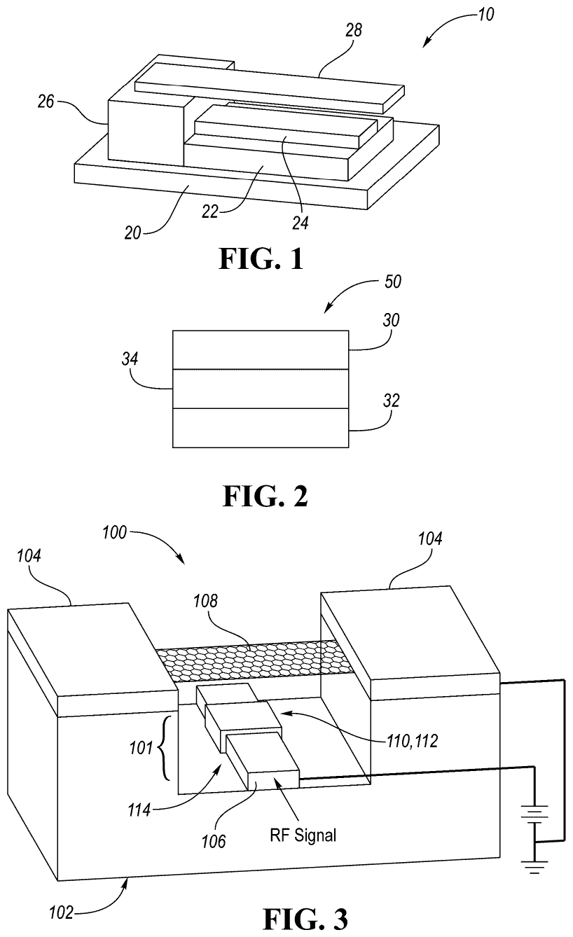

Recently, nanotechnology use cases have been applied in various sectors, from medicine and information technology to transportation, food, retail, and others. In the world of electronics, non-limiting example technologies which are being shrunk to the nanoscale include quantum sensors, quantum dots, nanoelectromechanical systems (NEMS), semiconductor memory, and biomolecule sensors, molecular circuits, transistors (field-effect transistors), nanodiodes, photovoltaic cells, and photonic antennas, etc. A non-limiting schematic example of a nanotechnology device, specifically a NEMS is shown in FIG. 1. The non-limiting example device 10 includes a silicon substrate 20, a silicon dioxide layer 22 supporting the bottom electrode 24, and a beam supporting block 26 supporting a suspended electrode 28.

Electronic nanoscale devices typically include two current collectors (CC) that sandwich a dielectric whose width is in the order of about 10 nm (about 3 to 100 nm). The dielectric prevents or modulates current transfer from the first CC to the second CC, as shown schematically in FIG. 2. In FIG. 2, the device 50 includes CC 30 and 32, and dielectric 34. The current typically transfers in some other way, e.g. through a sensing molecule, through a quantum dot, through a semiconductor logic gate, etc.

Typically, the dielectric has a disadvantage in that the dielectric needs to have a relatively high dielectric constant (“high-K”). One state of the art material is Al₂O₃, crystalline or amorphous alumina, where K˜9. Yet, a deposition of Al₂O₃ often requires a high-temperature annealing stage at about 300° C. to cure pinhole defects during deposition. The annealing stage is thought to reduce dielectric properties by introducing oxygen defects in the layer which allow some conductivity from the first CC to the second CC.

Other dielectric materials have been developed for the nanoscale dielectric purposes, including various polymers. But the polymers often degrade at temperatures above about 100-300° C., making the polymers unavailable for high-temperature applications or where high-temperature processing is necessary for the device. An alternative group of materials include perovskites such as BaTiO₃ that have high dielectric properties. But these materials are often difficult or expensive to deposit; they are sometimes toxic; and defects are common during deposition. In other oxides such as alumina and hafnia, high temperature frequently induces defects that reduce dielectric properties.

Therefore, there is a need for an alternative material which would be suitable as a dielectric in a nano device.

In one or more embodiments, a material is disclosed. The material is a dielectric material or a material having the property of screening an electric field, or being polarized in response to an electric field. The material is a nano or nanoscale material. Nano or nanoscale refers to dimensions between about 1-100 nm. The material is a nano dielectric material.

The material may be a part or portion of a structure, component, unit, cell, device, system such as a nanoscale structure component, unit, cell, device, system. A non-limiting example of the structure, component, unit, cell, device, system may include quantum sensors, quantum dots, nanoelectromechanical systems (NEMS), semiconductor memory, and biomolecule sensors, molecular circuits, transistors (field-effect transistors), nanodiodes, photovoltaic cells, and photonic antennas, etc. Optical devices such as nanophotonics and bio devices such as biosensing devices may likewise include the disclosed material as a dielectric.

The material may form a dielectric layer or surface portion. The layer or surface portion may have a height or thickness of about, at least about, or at most about 3-100, 5-80, or 8-50 nm. The height or thickness may be about 3, 5, 8, 10, 15, 20, 25, 30, 35, 40, 45, 50, 55, 60, 65, 70, 75, 80, 85, 90, 95, or 100 nm. The layer or surface portion may have a width which is about or at least about 10, 11, 12, 13, 14, 15, 16, 17, 18, 19, 20, 21, 22, 23, 24, 25, 26, 27, 28, 29, 30, 35, 40, 45, 50, 55, 60, 65, 70, 75, 80, 85, 90, 95, 100, 105, 110, 120, 130, 140, 150, 200, 250, or more time greater than its height.

The material is a stable dielectric or a material that may have low or substantially zero electrical conductivity. The material is polarizable. Electric charges are screened by the material when the dielectric is placed in an electric field. The material has a dielectric constant of no less than about or about 10. The material may have a dielectric constant higher than about 10.

The material may have a bandgap of about or at least about 2, 3, or 4 eV. The material may have a bandgap of about or at least about 2.0, 2.1, 2.2, 2.3, 2.4, 2.5, 2.6, 2.7, 2.8, 2.9, 3.0, 3.1, 3.2, 3.3, 3.4, 3.5, 3.6, 3.7, 3.8, 3.9, 4.0, 4.1, 4.2, 4.3, 4.4, 4.5, 4.6, 4.7, 4.8, 4.9, or 5.0. Bandgap is a difference in energy between the valence band and the conduction band of the material that consist of the range of energy values forbidden to electrons in the material. The bandgap represents the minimum energy that is required to excite a single electron up to a state in the conduction band where it can participate in conduction.

The material may form a dielectric in a nanogap such that the dielectric is arranged between two electrodes separated by no more than about a predetermined distance of about 2-120, 3-100, 5-80, or 5-50 nm. The predetermined distance may be about 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, or 120 nm.

Nanogap electrodes are building blocks for the fabrication of nano devices and circuits. Nanogap electrodes include two electrodes facing each other across a nanometer separation. The material disclosed herein is structured to prevent vacancy conduction in the nanogap.

A non-limiting example structure, component, unit, cell, device, or system including the nano dielectric material disclosed herein is shown in FIG. 3. FIG. 3 shows an example NEMS graphene capacitive switch 100 with a nanogap 101. The switch 100 includes a substrate 102, ground conductors (electrodes) 104, a central conductor (electrode) 106, a graphene or chemical monolayer membrane 108 bridging the nanogap 101, and a dielectric 110 including the material disclosed herein. The dielectric may form a surface portion. The surface portion 112 relates to a layer or film adjacent to the top of a bulk portion 114. The bulk portion may be a substrate such as 102 or central conductor 106, or their combination, or a different bulk portion.

The surface portion may be immediately adjacent to the top of the bulk portion. The layer or film may be continuous or discontinuous. The layer or film may have the same or different thickness across the area covering the bulk material. The layer or film may include at least one, more than one or one layer or film.

The surface portion may include one or more compositions or compounds disclosed herein. The material may be doped with one or more elements. The material may include oxygen vacancies purposefully created and maintained in the material. The material may be non-stoichiometric. For example, oxygen deficiency may result in a material including O_{2-δ}, where 0≤δ<0.5. A non-limiting example composition may be NdO_{2-δ}, where 0≤δ<0.5. Even if the material includes an oxygen vacancy, it is desired that the material remains to be a stable dielectric and not conducting electric charges between the current collectors.

The material may include, comprise, consist essentially of, or consist of at least one or one or more binary oxide compounds having a general formula (I):

(Nd,Sr,Ca)O₂ (I),

The material may include one, two, or three compounds of formula (I), specifically NdO₂, SrO₂, CaO₂, of their combination.

The material may include, comprise, consist essentially of, or consist of at least one or one or more chromium oxide compounds having a general formula (II):

M_{1-x-y}CrₓO_{y} (II),
where
M is a metal,
x is any number between 0.077 and 0.114 or 0.179 and 0.3,
y is any number between 0.618 and 0.75.

In the formula (II), M may be a metal, alkali metal, alkali earth metal, transition metal, lanthanoid. In the formula (II), M may be an element from the I.A, II.A, III.B, IV.B, V.B, VI.B, VII.B, or VIII.B group of the Periodic Table of Elements. M may be an element from the fourth, fifth, sixth, or seventh period of the Periodic Table of Elements. M may be Li, Rb, K, La, Sr, Sc, Ti, V, Mn, Fe, Co, Ni, Cu, Zn, Y, Zr, Nb, Mo, Tc, Ru, Rh, Pd, Ag, Cd, Hf, Ta, W, Re, Os, Ir, Pt, Au, Rf, Db, Sg, Bh, Hs, Mt, Ds, Rg, or Cn. One or more elements may be excluded from the list.

In the formula (II), x may be any number between 0.077 and 0.114 or 0.179 and 0.3. x may be 0.077, 0.078, 0.079, 0.080, 0.081, 0.082, 0.083, 0.084, 0.085, 0.086, 0.087, 0.088, 0.089, 0.090, 0.091, 0.092, 0.093, 0.094, 0.095, 0.096, 0.097, 0.098, 0.100, 0.101, 0.102, 0.103, 0.104, 0.105, 0.106, 0.107, 0.108, 0.109, 0.110, 0.111, 0.112, 0.113, or 0.114. x may be 0.179, 0.180, 0.181, 0.182, 0.183, 0.184, 0.185, 0.186, 0.187, 0.188, 0.189, 0.190, 0.191, 0.192, 0.193, 0.194, 0.195, 0.196, 0.197, 0.198, 0.199, 0.200, 0.205, 0.210, 0.215, 0.220, 0.225, 0.230, 0.235, 0.240, 0.245, 0.250, 0.255, 0.260, 0.265, 0.270, 0.275, 0.280, 0.285, 0.290, 0.295, or 0.300.

In the formula (II), y may be any number between 0.618, 0.619, 0.620, 0.621, 0.622, 0.623, 0.625, 0.630, 0.635, 0.640, 0.645, 0.650, 0.655, 0.660, 0.665, 0.670, 0.675, 0.680, 0.685, 0.690, 0.695, 0.700, 0.705, 0.710, 0.715, 0.720, 0.725, 0.730, 0.735, 0.740, 0.745, or 0.750.

Non-limiting examples of compounds of formula II may include Rb_{0.18}Cr_{0.18}O_{0.64}, La_{0.22}Cr_{0.11}O_{0.67}, K_{0.18}Cr_{0.18}O_{0.64}, Li_{0.18}Cr_{0.18}O_{0.64}, Sr_{0.18}Cr_{0.18}O_{0.64}, or their combination.

The material may include, comprise, consist essentially of, or consist of at least one or one or more vanadium oxide compounds having a general formula (III):

MₓV_{y}O_{1-x-y} (III),
where
M is a metal,
x is any number greater than 0.1,
y is any number greater than 0.138.

In the formula (III), M may be a metal, alkali metal, alkaline earth metal, transition metal. In the formula (III), M may be an element from the I.A, II.A, III.B, IV.B, V.B, VI.B, VII.B, or VIII.B group of the Periodic Table of Elements. M may be an element from the second, third, fourth, fifth, sixth, or seventh period of the Periodic Table of Elements. M may be Mg, Na, Ta, Y, Sc, Ti, V, Mn, Fe, Co, Ni, Cu, Zn, Zr, Nb, Mo, Tc, Ru, Rh, Pd, Ag, Cd, Hf, W, Re, Os, Ir, Pt, Au, Rf, Db, Sg, Bh, Hs, Mt, Ds, Rg, or Cn. One or more elements may be excluded from the list.

In the formula (III), x may be any number greater than 0.1. x may be about or greater than about 0.1, 0.105, 0.110, 0.115, 0.120, 0.125, 0.130, 0.135, 0.140, 0.145, 150, 0.155, 0.160, 0.165, 0.170, 0.175, 0.180, 0.185, 0.190, 0.195, 0.200, 0.205, 0.210, 0.215, 0.220, 0.225, 0.230, 0.235, 0.240, 0.245, 0.250, 0.255, 0.260, 0.265, 0.270, 0.275, 0.280, 0.285, 0.290, 0.295, 0.300, etc.

In the formula (III), y may be any number greater than 0.138. y may be about or greater than about 0.138, 0139, 0.140, 0.141, 0.142, 0.143, 0.144, 0.145, 0.146, 0.147, 0.148, 0.149, 0.150, 0.155, 0.160, 0.165, 0.170, 0.175, 0.180, 0.185, 0.190, 0.195, 0.200, 0.205, 0.210, 0.215, 0.220, 0.225, 0.230, 0.235, 0.240, 0.245, 0.250, 0.255, 0.260, 0.265, 0.270, 0.275, 0.280, 0.285, 0.290, 0.295, 0.300, etc.

Non-limiting examples of compounds of formula III may include Mg_{0.18} V_{0.18}O_{0.64}, Na_{0.2}V_{0.2}O_{0.6}, Ta_{0.15}V_{0.15}O_{0.7}, Y_{0.17}V_{0.17}O₄, or their combination.

The material may include, comprise, consist essentially of, or consist of at least one or one or more magnesium vanadium oxide compounds having a general formula (IIIa):

MgₓV_{y}O_{1-x-y} (IIIa),
where
x is any number greater than 0.1,
y is any number greater than 0.138.

In the formula (IIIa), x may be any number greater than 0.146. x may be about or greater than about 0.147, 0.148, 0.149, 0.150, 0.155, 0.160, 0.165, 0.170, 0.175, 0.180, 0.185, 0.190, 0.195, 0.200, 0.205, 0.210, 0.215, 0.220, 0.225, 0.230, 0.235, 0.240, 0.245, 0.250, 0.255, 0.260, 0.265, 0.270, 0.275, 0.280, 0.285, 0.290, 0.295, 0.300, etc.

In the formula (IIIa), x may be any number greater than 0.1. x may be about or greater than about 0.1, 0.105, 0.110, 0.115, 0.120, 0.125, 0.130, 0.135, 0.140, 0.145, 150, 0.155, 0.160, 0.165, 0.170, 0.175, 0.180, 0.185, 0.190, 0.195, 0.200, 0.205, 0.210, 0.215, 0.220, 0.225, 0.230, 0.235, 0.240, 0.245, 0.250, 0.255, 0.260, 0.265, 0.270, 0.275, 0.280, 0.285, 0.290, 0.295, 0.300, etc.

Non-limiting examples of compounds of formula IIIa may include Mg_{0.18}V_{0.18}O_{0.64}, Mg_{0.2}V_{0.13}O_{0.53}, or their combination.

The material may include, comprise, consist essentially of, or consist of at least one or one or more oxide compounds having a general formula (IV):

NaₓMO_{y} (IV),
where
M is a transition metal,
x is any number between 0.15 and 0.6,
y is any number between 0.45 and 0.75.

In the formula (IV), M may be a transitional metal. In the formula (IV), M may be an element from the III.B, IV.B, V.B, VI.B, VII.B, or VIII.B group of the Periodic Table of Elements. M may be an element from the fourth, fifth, sixth, or seventh period of the Periodic Table of Elements. M may be V, Mo, Sn, Sc, Ti, V, Mn, Fe, Co, Ni, Cu, Zn, Y, Zr, Nb, Mo, Tc, Ru, Rh, Pd, Ag, Cd, Hf, Ta, W, Re, Os, Ir, Pt, Au, Rf, Db, Sg, Bh, Hs, Mt, Ds, Rg, or Cn. One or more elements may be excluded from the list.

In the formula (IV), x may be any number between 0.15 and 0.6. x may be about 0.15, 0.16, 0.17, 0.18, 0.19, 0.20, 0.21, 0.22, 0.23, 0.24, 0.25, 0.26, 0.27, 0.28, 0.29, 0.30, 0.31, 0.32, 0.33, 0.34, 0.35, 0.36, 0.37, 0.38, 0.39, 0.40, 0.41, 0.42, 0.43, 0.44, 0.45, 0.46, 0.47, 0.48, 0.49, 0.50, 0.51, 0.52, 0.53, 0.54, 0.55, 0.56, 0.57, 0.58, 0.59, or 0.60.

In the formula (IV), y may be any number between 0.45 and 0.75. y may be about 0.45, 0.46, 0.47, 0.48, 0.49, 0.50, 0.51, 0.52, 0.53, 0.54, 0.55, 0.56, 0.57, 0.58, 0.59, 0.60, 0.61, 0.62, 0.63, 0.64, 0.65, 0.66, 0.67, 0.68, 0.69, 0.70, 0.71, 0.72, 0.73, 0.74, or 0.75.

Non-limiting examples of compounds of formula IV may include Na_{0.2}V_{0.2}O_{0.6}, Na_{0.28}Mo_{0.14}O_{0.58}, Na_{0.44}Sn_{0.11}O_{0.45}, or their combination.

The material may include, comprise, consist essentially of, or consist of at least one or one or more zinc nitride compounds having a general formula (V):

MₓZn_{y}N_{1-x-y} (V),
where
M is an alkali metal,
y is about 0.0667,
x is about 0.1333.

In the formula (V), M may be an alkali metal. M may be Li, Na, K, Rb, Cs, or Fr. One or more elements may be excluded from the list.

Non-limiting examples of compounds of formula V may include K₂ZnN₁₂, Rb₂ZnN₁₂, Cs₂ZnN₁₂, or their combination.

The material may include, comprise, consist essentially of, or consist of at least one or one or more silicon nitride compounds having a general formula (VI):

M_{y}SiₓN_{1-x-y} (VI),
where
M is an alkali earth metal,
x is any number greater than 0.387,
y is any number smaller than or equal to 0.07.

In the formula (VI), M may be an alkali earth metal. M may be Be, Mg, Ca, Sr, or Ba. One or more elements may be excluded from the list.

In the formula (IV), x may be any number greater than 0.387. x may be about or greater than about 0.388, 0.389, 0.390, 0.395, 0.400, 0.405, 0.410, 0.415, 0.420, 0.425, 0.430, 0.435, 0.440, 0.445, 0.450, etc.

In the formula (IV), y may be any number smaller than 0.07. y may be about or smaller than about 0.07, 0.065, 0.06, 0.055, 0.05, 0.045, 0.04, 0.035, 0.03, 0.025, 0.02, 0.015, 0.01, 0.005, etc.

Non-limiting examples of compounds of formula VI may include Sr_{0.07}Si_{0.4}N_{0.53}, Ba_{0.07}Si_{0.4}N_{0.53} or their combination.

A method of forming the nan dielectric material is disclosed herein. The method may include forming a nanoscale film or a surface portion by one or more techniques. For example, the method may include forming the film by vapor deposition such as atomic layer deposition (ALD), which is a relatively low-temperature process reaching up to about 300° C. ALD is also relatively efficient from energy standpoint. The ALD technique may be used especially for small dimensions such as less than about 5 nm to about 100 nm.

The method may include ALD with a (thd)-based precursor (thd=2,2,6,6-tetramethyl-3,5-heptanedione). The method may include an ozone (O₃) precursor. The method may include a particular pulse pattern. The method may include a ZnEt₂ (Et=ethyl C₂H₅) precursor.

The method of forming the film may include material sputtering such as direct sputtering, RF frequency, evaporation such as ebeam, thermal, laser, electrochemical deposition, or electroplating. The latter techniques may be used especially for thicker films such as up to about 100 nm. The method may include providing excess oxygen by varying pressure, temperature, changing the oxygen source(s), or adding a further step of oxidation after ALD, or a combination thereof.

The method may include providing a screen over a component, depositing the material over the screen, and removing the screen, for example by etching the screen away. The method may include etching away regular intervals of the applied material. The method may include annealing of the material at an elevated temperature above about 100° C. to reduce a number of defects present in the deposited material. The method may include exposing the deposited material to an oxidizing environment to increase the amount of oxygen in the deposited material. The exposing may be done subsequently to or after deposition, etching, annealing, or a combination thereof.

The method may include doping or purposefully forming and preserving oxygen deficiencies in the material.

### Experimental Section

The following conditions were considered in a search for a suitable dielectric material disclosed herein:
(A) dielectric constant of equal to or more than 10;
(B) a material including MOₓ or MNₓ, where an excess or deficiency of oxygen or nitrogen (respectively) will not create conducting states; and
(C) manufacturing capability via ALD including the ability to grow the material using a 2,2,6,6-tetramethyl-3,5-heptanedione (thd) and an ozone precursor.

The one or more oxides of formulas (I)-(VI) were identified using publicly available materials database to screen for the optimal materials, and high-throughput (HT) first-principles density functional theory (DFT) was used to calculate the results to evaluate and identify suitable getters materials.

The following screening criteria were used:
(a) Total energy of a computed structure (typically in e V/atom or eV) describes the computed energy of a structure; the differences between structures correspond to a reaction energy between those structures. For example, the reaction A→B has a reaction energy E_{B}−E_{A} (where the energies might be written in kJ/mol);
(b) Convex-hull decomposition (or decomposition)—the convex hull of all stable compositions may be constructed such that each chemical composition C has a minimum combination of stable states, C→A+B, where the stoichiometric formula of C is equal to the sum of A and B, and there is no other A′+B′ that has a lower energy. Then A+B is the convex-hull decomposition products of C. If the energy of C is known, then the hull energy or decomposition energy (typically eV/atom or eV) is Eₕ=E_{C}−E_{A}−E_{B} and is always a nonnegative number. In some conventions it is reported as the reaction energy Eᵣₓₙ=E_{A}+E_{B}−E_{C} and is always a nonpositive number.

The screening-gained information was used to explore various classes of chemicals: known materials whose DFT structure can be computed; typically single-crystal or gas-phase molecules as well as compositional formulas, even if the atomic structure is not known, as long as related structures are available in a database. This includes: adjusting compositional ratios such as excess oxygen or oxygen vacancies and dopants and substitutions.

Several properties were computed:

1. Stability at a fixed temperature—this can be given by the hull energy; if it is less than the temperature (times the Boltzmann constant kB), then it is stable. Alternatively, it can be computed by the oxygen chemical potential, which can be benchmarked to temperature at a known scale.

2. Filtering by atom size, oxidation state, metal-oxygen ratio, crystal structure, spacegroup, elements, etc.

3. Elemental material cost, per mol or per kg.

4. Bandgap—although dielectric constants are typically not listed in computational databases—because they depend on the response of the electrons to an external field—the bandgap is often available. It was observed that most dielectrics have an experimental bandgap at least 3-4 eV (e.g. TiO₂, BaO, Ta₂O₅). Because the DFT method characteristically underestimates the bandgap, a cutoff of 2 eV was used (similar to that of TiO₂).

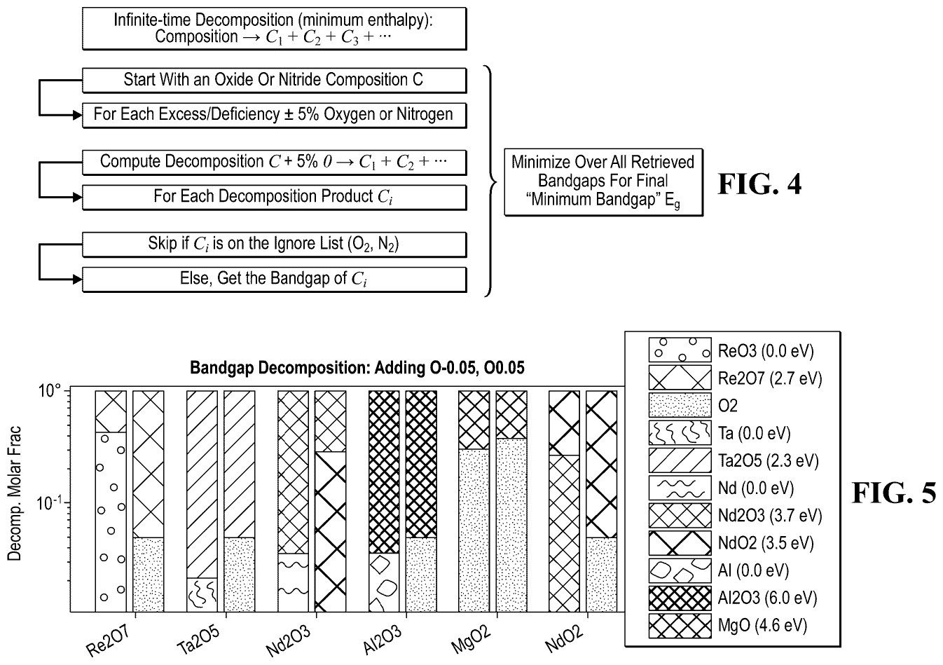

5. Bandgap stability is defined by the minimum bandgap of a composition C+X decomposition products. The minimum bandgap of all decomposition products was used as a scalar metric for bandgap stability. A non-limiting example algorithm used for bandgap screening of decomposition products is shown in FIG. 4.

The bandgap stability was computed for several binary oxides and the results are shown in Table 1 below. Reaction products of oxides with deficient and excess oxygen, respectively, were assessed. Two non-limiting representative examples are described below.
(a) Al₂O₃ with deficient oxygen forms 0.035 Al+0.965 Al₂O₃. Al is conducting (bandgap 0.0 eV) which flags it as “unsuitable.” Al₂O₃ with excess oxygen forms 0.048 02+0.952 Al₂O₃. O₂ is on the “ignore” list because any unstable oxygen is not going to form an unstable state, oxygen would evaporate during the high-temperature processing. Therefore, the final metric of Al₂O₃ is 0.0.
(b) NdO₂ with deficient oxygen forms 0.263 Nd₂O₃+0.737 NdO₂. These bandgaps are 3.7 and 3.5 eV, respectively. NdO₂ with excess oxygen forms 0.95NdO₂+0.05O₂. NdO₂ has a bandgap of 3.5 eV, as was revealed by the previous calculation, and O₂ is on the “ignore” list because any unstable oxygen is not going to form an unstable state but evaporate during the high-temperature processing. The final metric of NdO₂ is 3.5 eV.

TABLE 1
Bandgap stability for oxides of (a) and (b)

| Original | Added | Reaction | Decomp. | Decomp. | Decomp. | Decomp. |
|---|---|---|---|---|---|---|
| formula | formula | formula | product | mol. fract. | wt. fract. | bandgap |
| Nd₂O₃ | O_{-0.05} | Nd₂O_{2.75} | Nd | 0.035 | 0.008 | 0.000 |
| Nd₂O₃ | O_{-0.05} | Nd₂O_{2.75} | Nd₂O₃ | 0.965 | 0.992 | 3.711 |
| Nd₂O₃ | O_{0.05} | Nd₂O_{3.25} | NdO₂ | 0.286 | 0.05 | 3.514 |
| Nd₂O₃ | O_{0.05} | Nd₂O_{3.25} | Nd₂O₃ | 0.714 | 0.95 | 3.711 |
| Al₂O₃ | O_{-0.05} | Al₂O_{2.75} | Al | 0.035 | 0.005 | 0.000 |
| Al₂O₃ | O_{-0.05} | Al₂O_{2.75} | Al₂O₃ | 0.965 | 0.995 | 6.044 |
| Al₂O₃ | O_{0.05} | Al₂O_{3.25} | O₂ | 0.048 | 0.03 | 1.369 |
| Al₂O₃ | O_{0.05} | Al₂O_{3.25} | Al₂O₃ | 0.952 | 0.97 | 6.044 |
| NdO₂ | O_{-0.05} | NdO_{1.85} | Nd₂O₃ | 0.263 | 0.732 | 3.711 |
| NdO₂ | O_{-0.05} | NdO_{1.85} | NdO₂ | 0.737 | 0.268 | 3.514 |
| NdO₂ | O_{0.05} | NdO_{2.15} | O₂ | 0.048 | 0.018 | 1.369 |
| NdO₂ | O_{0.05} | NdO_{2.15} | NdO₂ | 0.952 | 0.982 | 3.514 |

(c) Other materials, shown in FIG. 5, were tested in a similar way as (a) and (b). The tested materials included Re₂O₇, Ta₂O₅, and MgO₂, Nd₂O₃, Al₂O₃, and NdO₂ are also shown in FIG. 5. It can be observed from FIG. 5 that Re₂O₇ has a metric of 0 (can form ReO₃), Ta₂O₅ has 0 (can form Ta), and MgO₂ has 4.6 (forms MgO and excess oxygen).

Based on the above, material screenings were conducted. Throughout the screenings, the following conditions were added to (A)-(C) discussed above:
(D) stability at room temperature—the hull energy below about 25 meV/atom;
(E) non-radioactive material;
(F) a bandgap of at least 2 eV, which is closely correlated with a dielectric material.

The screening generated three search spaces within the described criteria:
(I) Binary oxides (267 materials);
(II) Ternary oxides (1811 materials); and
(III) Binary and ternary nitrides (120 materials).

Ranking of the found materials was based on the following criteria:
Metric #1: DFT bandgap; a higher bandgap is loosely correlated with higher dielectric properties.
Metric #2: Bandgap stability as described above. A higher bandgap stability is desired, of at least 1 eV after a small compositional change.
Metric #3: Elemental cost should be minimized when possible.

The materials were compared against ALD and other decomposition methods for manufacturability.

### Binary Oxides

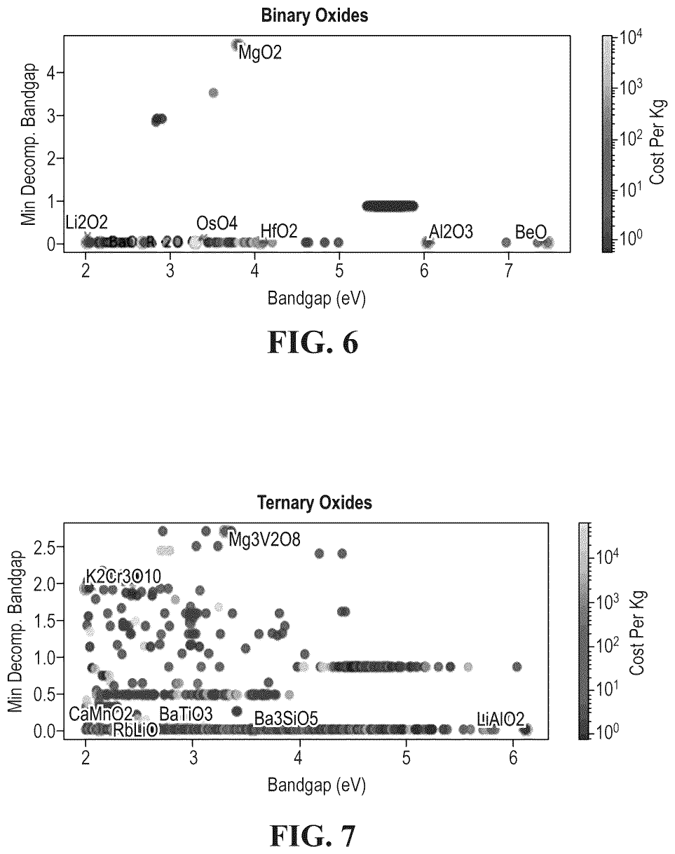

FIG. 6 shows a scatter plot of metrics #1-3 for the 267 binary oxide materials identified in the search space. As can be observed from FIG. 6, most binary oxides failed the minimum decomposition bandgap test. The exceptions were the cluster of Si oxides at y=0.853 and the following materials: (Mg, Nd, Sr, Ca) O₂. Additional information for MgO₂, NdO₂, SrO₂, and CaO₂ is provided in Table 2 below. It is notable that several common dielectrics such as Al₂O₃ and HfO₂ likewise failed the test. Additionally, MgO₂ spontaneously decays into MgO and is therefore unstable unless the chemical potential of oxygen is very weak.

TABLE 2
Binary oxides screening

| Material | Insulator | | Min. |
|---|---|---|---|
| formula | decomposition products | Decomposition reaction O_{-0.05} | bandgap [eV] |
| MgO₂ | MgO, O₂ | MgO_{1.85} → MgO + 0.425 O₂ | 4.638 |
| NdO₂ | Nd₂O₃, NdO₂, O₂ | NdO_{1.85} → 0.7 NdO₂ + 0.15 Nd₂O₃ | 3.514 |
| SrO₂ | SrO, SrO₂, O₂ | SrO_{1.85} → 0.85 SrO₂ + 0.15 SrO | 2.836 |
| CaO₂ | CaO, CaO₂, O₂ | CaO_{1.85} → 0.85 CaO₂ + 0.15 CaO | 2.906 |

### Ternary Oxides

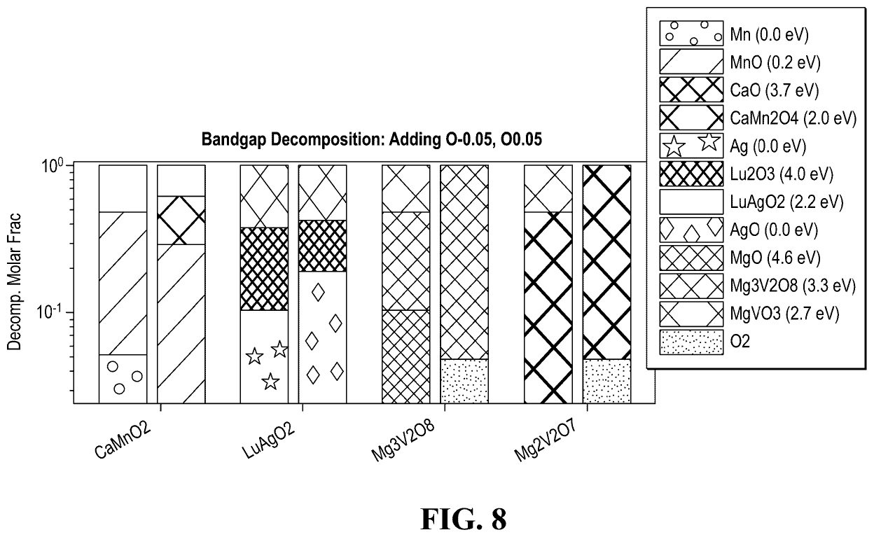

FIG. 7 shows a plot of metrics #1-3 for the 1811 ternary oxide materials identified in the search space. Table 3 below summarizes some of the studied materials and screening criteria. In Table 3, the suitable values are denoted as bold, the most suitable results are denoted as bold and underlined, and the least suitable values are denoted in Italics. The bandgap decomposition was further assessed for several promising families of materials, as shown in FIG. 8.

TABLE 3
Ternary oxides screening

| Material formula | Bandgap [eV] | Min. bandgap [eV] | Cost per kg |
|---|---|---|---|
| Mg₂V₂O₇ | 2.725 | 2.697 | 12.527 |
| Mg₃V₂O₈ | 3.367 | 2.697 | 11.416 |
| NaVO₃ | 3.039 | 2.493 | 59.436 |
| Rb₂Cr₂O₇ | 2.702 | 2.434 | 35211.211 |
| Na₂MoO₄ | 4.190 | 2.393 | 72.646 |
| La₂CrO₆ | 2.160 | 2.160 | 229.419 |
| K₄SnO₄ | 2.342 | 2.110 | 473.914 |
| Na₂SnO₃ | 2.260 | 2.103 | 74.091 |
| Cr₂(Bi₂O₅)₃ | 2.357 | 2.018 | 20.486 |
| Na₃ReO₅ | 2.445 | 1.996 | 2646.256 |
| Rb₂Cr₃O₁₀ | 2.028 | 1.931 | 27980.758 |
| CrPbO₄ | 2.036 | 1.922 | 2.75 |
| K₂Cr₃O₁₀ | 2.003 | 1.915 | 200.657 |
| K₂Cr₂O₇ | 2.703 | 1.915 | 267.898 |
| TaVO₅ | 2.172 | 1.900 | 200.044 |
| KVO₃ | 3.073 | 1.890 | 294.106 |
| Na₂Cr₂O₇ | 2.525 | 1.870 | 46.226 |
| Li₂Cr₂O₇ | 2.381 | 1.857 | 2.908 |
| BeCrO₄ | 2.429 | 1.822 | 34.948 |
| SrCr₂O₇ | 2.484 | 1.822 | 2.36 |
| BaCr₂O₇ | 2.625 | 1.822 | 1.841 |
| Na₄SnO₄ | 2.096 | 1.772 | 99.397 |
| Lu₂Sn₂O₇ | 2.843 | 1.767 | 3765.098 |
| DyVO₄ | 2.984 | 1.670 | 298.44 |
| Cs₂CrO₄ | 3.247 | 1.669 | 45880.545 |
| HgMoO₄ | 2.338 | 1.649 | 39.488 |
| Li₂MoO₄ | 4.401 | 1.602 | 20.238 |
| ErVO₄ | 2.967 | 1.584 | 435.251 |
| TmVO₄ | 2.961 | 1.582 | 3873.165 |
| LiNbO₃ | 2.743 | 1.579 | 15.73 |
| KSnO₂ | 2.209 | 1.578 | 228.198 |
| HoVO₄ | 2.982 | 1.571 | 712.689 |
| YVO₄ | 2.977 | 1.563 | 203.841 |
| NdVO₄ | 3.024 | 1.560 | 256.389 |
| Ca₂PbO₄ | 2.028 | 1.539 | 3.239 |
| Ca₂V₂O₇ | 2.978 | 1.523 | 11.685 |
| SmVO₄ | 3.011 | 1.517 | 175.888 |

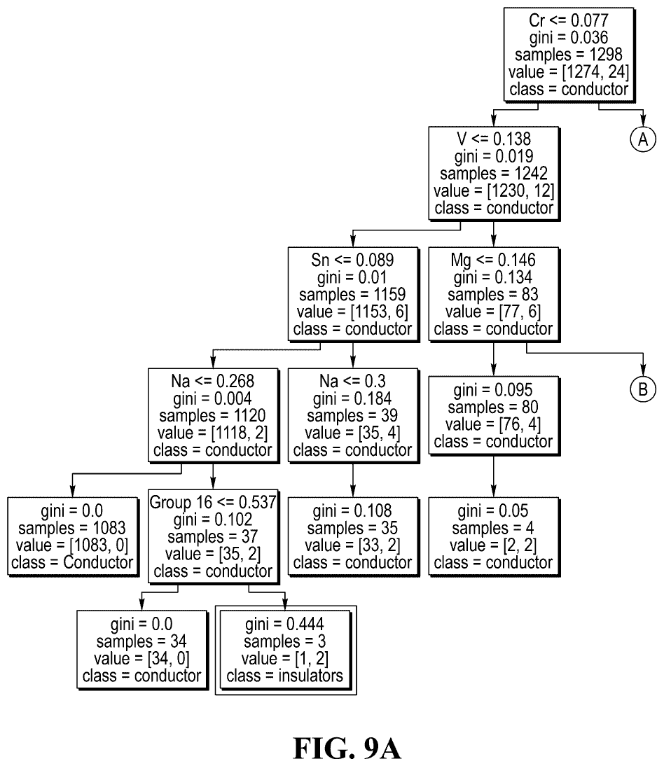

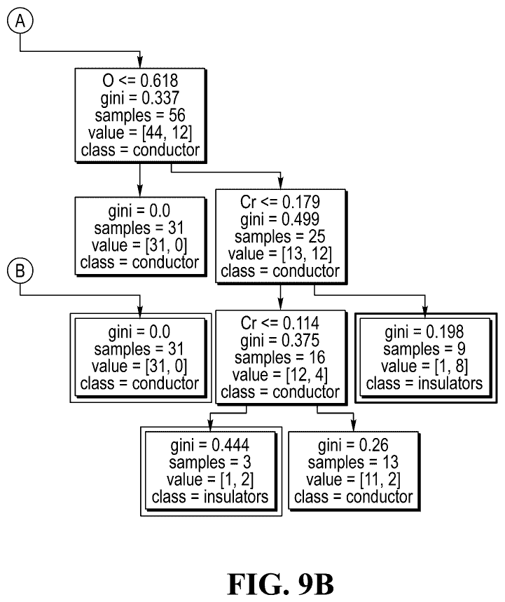

A decision tree was generated to further isolate the materials most suitable for the dielectric use case described herein. The decision tree, shown in FIG. 9, was generated with a typical sklearn DecisionTreeClassifier, with maximum depth of 12, minimum splitting of 5 samples with 2 samples on each leaf, and a cost complexity pruning parameter of 9e-4. The dataset was partitioned into 1298 samples, 1274 of which have a minimum bandgap less than 1.7 eV and 24 of which are greater. Due to the scarcity of data, a partition into a test and train set was not conducted. Each node in the diagram gave five quantities: (a) The decision point in molar fraction, e.g. Cr≤0.08 corresponds to “True” if the molar quantity of Cr is less than 8% and “False” otherwise. (b) The Gini impurity gives the quality of the leaf (how well it distinguishes). (c) Samples are the number of samples at that node. (d) The value gives the number of samples in each node that are conductors or insulators, respectively. (5) Class is the average class of the node; the purity of a node is denoted as follows: where gray marked a bandgap<1.7 and a double border denotes a bandgap>1.7.

### Binary and Ternary Nitrides

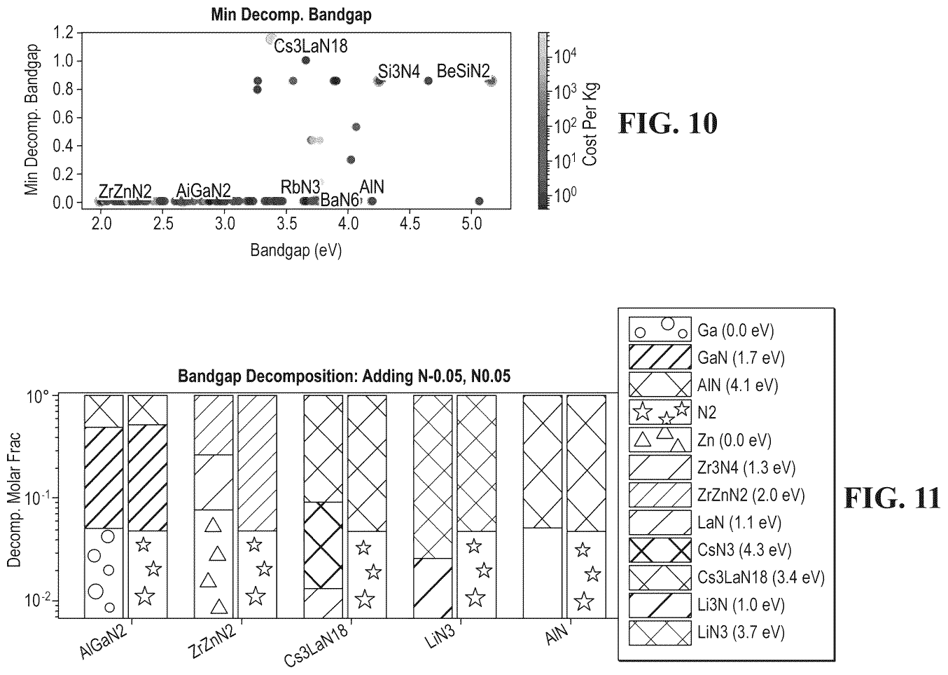

FIG. 10 shows a scatter plot of metrics #1-3 for the 120 binary and ternary nitrides materials identified in the search space. Table 4 below summarizes some of the studied materials and screening criteria. In Table 4, the suitable values are denoted as bold, the most suitable results are denoted as bold and underlined, and the least suitable values are denoted in Italics. The bandgap decomposition was further assessed for several promising nitride materials, as shown in FIG. 11.

TABLE 4
Nitrides screening

| Material formula | Bandgap [eV] | Min. bandgap [eV] | Cost per kg |
|---|---|---|---|
| Cs₃LaN₁₈ | 3.389 | 1.149 | 33332.874 |
| LiN₃ | 3.664 | 0.999 | 1.051 |
| Sr(Si₃N₄)₂ | 3.277 | 0.853 | 1.165 |
| BeSiN₂ | 3.562 | 0.853 | 62.928 |
| SrSi₇N₁₀ | 3.893 | 0.853 | 1.153 |
| BaSi₇N₁₀ | 3.912 | 0.853 | 0.893 |
| Si₃N₄ | 4.258 | 0.853 | 1.167 |
| BeSiN₂ | 5.166 | 0.853 | 62.928 |
| Ba(Si₃N₄)₂ | 3.274 | 0.791 | 0.869 |
| Mg(BeN)₂ | 4.073 | 0.526 | 116.735 |
| K₂ZnN₁₂ | 3.708 | 0.433 | 251.689 |
| Rb₂ZnN₁₂ | 3.726 | 0.433 | 33686.555 |
| Cs₂ZnN₁₂ | 3.783 | 0.433 | 35083.752 |
| MgSiN₂ | 4.031 | 0.294 | 2.246 |
| CsN₃ | 3.790 | 0.136 | 50070.218 |
| Ba₂Si₅N8 | 2.892 | 0.001 | 0.674 |

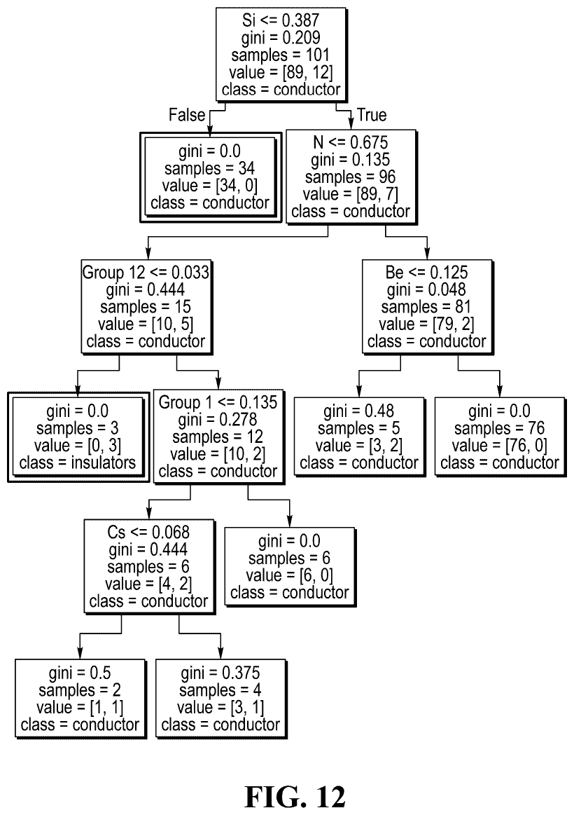

A decision tree was generated to further isolate the materials most suitable for the dielectric use case described herein. The decision tree, shown in FIG. 12, was generated with a typical sklearn DecisionTreeClassifier according to the conditions described above for ternary oxides. The cutoff was set at 0.4 eV. 12 matches were identified via the decision tree.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the disclosure that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A nanogap dielectric device comprising:
a pair of nano electrodes;
a nanogap separating the electrodes; and
a dielectric nano material located within the nanogap, the dielectric nano material comprising one or more compounds of formula (I):
(Nd,Ca)O₂ (I).

2. The device of claim 1, wherein the dielectric nano material has a bandgap of at least about 2 eV.

3. The device of claim 1, wherein the dielectric nano material has a dielectric constant of at least about 10.

4. The device of claim 1, wherein the dielectric nano material forms a layer having a thickness of about 3-100 nm and a width at least about 10 times greater than the thickness.

5. The device of claim 1, wherein the dielectric nano material is in contact with only one nano electrode from the pair of nano electrodes.

6. The device of claim 1, wherein the dielectric nano material further includes one or more compounds of formula (II):
M_{1-x-y}CrₓO_{y} (II),
where
M is a metal,
x is any number between 0.077 and 0.114 or 0.179 and 0.3, and
y is any number between 0.618 and 0.75.

7. The device of claim 1, wherein the material includes an oxygen vacancy such that the oxygen content is O_{2-δ}, where 0≤δ<0.5.

8. The device of claim 1, wherein the device is a nanoelectromechanical systems (NEMS) device.

9. A nanogap dielectric device comprising:
a substrate supporting a nano cathode and a nano anode separated from each other by a nanogap; and
a dielectric nano material located within the nanogap, the dielectric nano material comprising one or more compounds of formula (II):
M_{1-x-y}CrₓO_{y} (II),
where
M is a metal,
x is any number between 0.077 and 0.114 or 0.179 and 0.3, and
y is any number between 0.618 and 0.75.

10. The device of claim 9, wherein the dielectric nano material has a bandgap of at least about 2 eV.

11. The device of claim 9, wherein the dielectric nano material has a dielectric constant of at least about 10.

12. The device of claim 9, wherein the dielectric nano material forms a layer having a thickness of about 3-100 nm and a width at least about 10 times greater than the thickness.

13. The device of claim 9, wherein the dielectric nano material is in contact with the nano cathode or the nano anode.

14. The device of claim 9, wherein the dielectric nano material further includes one or more compounds of formula (III):
MₓV_{y}O_{1-x-y} (III),
where
M is a metal,
x is any number greater than 0.1, and
y is any number greater than 0.138.

15. The device of claim 1, wherein the device further includes a graphene or chemical monolayer membrane bridging the nanogap.

16. A nanogap dielectric device comprising:
a substrate supporting a first conductor and a second conductor, separated from the first conductor by a nanogap; and
a dielectric nano material located within the nanogap, the dielectric nano material comprising one or more compounds of formula (III):
MₓV_{y}O_{1-x-y} (III),
where
M is a metal,
x is any number greater than 0.1,
y is any number greater than 0.138.

17. The device of claim 16, wherein the dielectric nano material has a bandgap of at least about 2 eV.

18. The device of claim 16, wherein the dielectric nano material has a dielectric constant of at least about 10.

19. The device of claim 16, wherein the dielectric nano material is non-stoichiometric.

20. The device of claim 19, wherein the dielectric nano material is in contact with the first conductor and the substrate, but not with the second conductor.
